(19) United States
(12) Patent Application Publication
(10) Pub. No.: US 2025/0022832 A1
(43) Pub. Date: Jan. 16, 2025

(54) SEMICONDUCTOR MODULE, SEMICONDUCTOR DEVICE, AND VEHICLE

(71) Applicant: FUJI ELECTRIC CO., LTD., Kawasaki-shi (JP)

(72) Inventors: Tsubasa WATAKABE, Kawasaki-shi (JP); Akihiko IWAYA, Kawasaki-shi (JP); Yoko NAKAMURA, Kawasaki-shi (JP); Yuta TAMAI, Kawasaki-shi (JP); Mai SAITO, Kawasaki-shi (JP)

(73) Assignee: FUJI ELECTRIC CO., LTD., Kawasaki-shi (JP)

(21) Appl. No.: 18/902,173

(22) Filed: Sep. 30, 2024

Related U.S. Application Data
(63) Continuation of application No. PCT/JP2023/031780, filed on Aug. 31, 2023.

(30) Foreign Application Priority Data
Oct. 6, 2022 (JP) 2022-161588

(51) Int. Cl. H01L 23/00; H01L 23/02; H01L 23/31; H01L 23/34; H01L 23/498

(52) U.S. Cl. CPC H01L 24/37; H01L 23/3107; H01L 23/49822; H01L 24/40; H01L 23/02; H01L 23/34; H01L 2224/37011; H01L 2224/40225

(57) ABSTRACT

A semiconductor module, including: a circuit board including a semiconductor element having an electrode on an upper surface thereof; a lead bonded to the electrode by a bonding material; and a sealing material that seals the semiconductor element and the lead. The lead includes: a bonding portion bonded to the electrode, the bonding portion having a lower surface facing the electrode, and an upper surface opposite to the lower surface, and a plurality of recesses formed on the upper surface of the bonding portion. In a plan view of the semiconductor module, the bonding portion has a plurality of sides, and each recess has a bottom surface of a planar shape, the planar shape having a side extending in a direction that is not orthogonal to any of the sides of the bonding portion. Each of the recesses a barbed portion protruding from a wall surface thereof.

### CROSS-REFERENCE TO RELATED APPLICATIONS

This application is a continuation application of PCT Application No. PCT/JP2023/031780, filed Aug. 31, 2023, which claims the benefit of priority to Japanese Patent Application No. 2022-161588, filed Oct. 6, 2022, each of which is incorporated by reference herein in its entirety.

### TECHNICAL FIELD

The present invention relates to a semiconductor module, a semiconductor device, and a vehicle.

### BACKGROUND ART

Some power conversion devices such as an inverter device include a semiconductor device including a circuit board on which a semiconductor element such as an insulated gate bipolar transistor (IGBT), a power metal oxide semiconductor field effect transistor (power MOSFET), and a free wheeling diode (FWD) is mounted. The circuit board includes a wiring board in which a conductor pattern is provided on a surface of an insulating substrate, and a circuit component such as a semiconductor element disposed on the wiring board.

In this type of semiconductor device, a conductor plate called a lead or the like may be used as a conductive member that electrically connects an electrode provided on a surface (upper surface) on a side opposite to a surface facing a wiring board side in electrodes of the semiconductor element and the conductor pattern of the wiring board.

In the semiconductor device in which the electrode of the semiconductor element and the conductor pattern of the wiring board are electrically connected using the lead, various measures have been proposed in order to prevent delamination at an interface between the lead and a sealing material.

For example, Patent Literature 1 describes a semiconductor device in which a side wall of a dimple formed in a lead frame has a barb portion protruding inward, and the dimples communicate with each other by a groove portion.

In addition, for example, Patent Literature 2 describes a semiconductor device in which at least four barbed portions obtained by a part of an inner peripheral wall protruding inward are formed in each of a plurality of dimples formed in a lead frame. In addition, for example, Patent Literature 3 describes a semiconductor device in which a barbed portion obtained by a part of an inner peripheral wall protruding inward is formed in each of a plurality of dimples formed in a lead frame, and the plurality of dimples includes two types of dimples having different orientation of the barbed portion.

In addition, for example, Patent Literature 4 describes a semiconductor device in which a large dimple opening at least one main surface and a small dimple opening on the inner surface of the large dimple are formed on the main surface of a die pad in a lead frame.

In addition, for example, Patent Literature 5 describes a semiconductor device in which a plurality of rectangular recesses is disposed vertically and horizontally at substantially equal intervals in a portion other than a semiconductor element mounting region on a surface of a metal plate to which a semiconductor element is fixed.

### CITATION LIST

### Patent Literature

Patent Literature 1: JP 4086774 B2
Patent Literature 2: JP 6408431 B2
Patent Literature 3: JP 2017-005124 A
Patent Literature 4: JP 2015-060889 A
Patent Literature 5: JP 2004-186622 A

### SUMMARY OF INVENTION

### Technical Problem

In the above-described configuration for preventing delamination at the interface between the lead and the sealing material in the semiconductor device, recesses called dimples or the like formed on the surface of the lead have a shape having a wall surface parallel to the side of the lead in plan view, or are arranged in a direction orthogonal to the side of the lead. Therefore, when delamination occurs in the sealing material at a position corresponding to the side of the lead in plan view, delamination often propagates in a direction orthogonal to the side.

The present invention has been made in view of such a point, and one object is to prevent propagation of delamination at an interface between a lead bonded to an electrode of a semiconductor element by a bonding material and a sealing material.

### Solution to Problem

A semiconductor module according to one aspect of the present invention includes: a circuit board on which a semiconductor element is mounted; a lead that is bonded to an electrode on an upper surface of the semiconductor element by a bonding material; and a sealing material that seals the semiconductor element and the lead, in which the lead includes a plurality of recesses having a polygonal shape in which a bottom surface in plan view has a side extending in a direction not orthogonal to any of sides of a bonding portion on an upper surface of the bonding portion bonded to the electrode, the upper surface being opposite to a lower surface facing the electrode, and each of the plurality of recesses has a barbed portion protruding from a wall surface.

### Advantageous Effects of Invention

According to the present invention, it is possible to prevent propagation of delamination at an interface between a lead bonded to an electrode of a semiconductor element by a bonding material and a sealing material.

### BRIEF DESCRIPTION OF DRAWINGS

FIG. 1 is a top view illustrating a configuration example of a semiconductor device according to an embodiment.

FIG. 2 is a cross-sectional view taken along line A-A′ of the semiconductor device in FIG. 1.

FIG. 3 is an enlarged partial top view of a region R in FIG. 1.

FIG. 4 is a cross-sectional view taken along line B-B′, a cross-sectional view taken along line C-C′, and a cross-sectional view taken along line D-D′ of the portion illustrated in FIG. 3.

FIG. 5 is a top view describing a first step in an example of a method of forming a recess.

FIG. 6 is a cross-sectional view taken along line B-B′, a cross-sectional view taken along line C-C′, and a cross-sectional view taken along line D-D′ in FIG. 5.

FIG. 7 is a top view describing a second step in an example of a method of forming a recess.

FIG. 8 is a cross-sectional view taken along line B-B′, a cross-sectional view taken along line C-C′, and a cross-sectional view taken along line D-D′ in FIG. 7.

FIG. 9 is a top view describing recesses formed in the first step and the second step.

FIG. 10 is a top view describing a third step in an example of a method of forming a recess.

FIG. 11 is a cross-sectional view taken along line B-B′, a cross-sectional view taken along line C-C′, and a cross-sectional view taken along line D-D′ in FIG. 10.

FIG. 12 is a top view describing a conventional example of a recess for preventing delamination at an interface between a first bonding portion of a lead and a sealing material.

FIG. 13 is a cross-sectional view taken along line E-E′ of the portion illustrated in FIG. 12.

FIG. 14 is a top view describing a second example of a method of forming a barbed portion on a wall surface of a recess.

FIG. 15 is a perspective view describing a third example of a method of forming a barbed portion on a wall surface of a recess.

FIG. 16 is a cross-sectional view illustrating an example of a recess and an additional recess formed using a punch exemplified in FIG. 15.

FIG. 17 is a schematic plan view illustrating an example of a vehicle to which the semiconductor device according to the present invention is applied.

### DESCRIPTION OF EMBODIMENTS

Hereinafter, an embodiment of the present invention will be described in detail with reference to the drawings. Note that the X, Y, and Z axes in each of the drawings to be referred to are illustrated for the purpose of defining a plane and a direction in an exemplified semiconductor device or the like, and the X, Y, and Z axes are orthogonal to each other and form a right-handed coordinate system. In the following description, the X direction may be referred to as a left-right direction, the Y direction may be referred to as a front-rear direction, and the Z direction may be referred to as an up-down direction. In addition, a plane including the X axis and the Y axis may be referred to as an XY plane, a plane including the Y axis and the Z axis may be referred to as a YZ plane, and a plane including the Z axis and the X axis may be referred to as a ZX plane. These directions (front-rear, left-right, and up-down directions) and planes are terms used for convenience of description, and a correspondence relationship with the XYZ directions may change depending on an attachment orientation of the semiconductor device. For example, a heat dissipation surface side (cooler side) of the semiconductor device is referred to as a lower surface side, and the opposite side is referred to as an upper surface side. In addition, in the present specification, plan view means a case where an upper surface or a lower surface (XY plane) of the semiconductor device or the like is viewed from the Z direction. In addition, an aspect ratio and a size relationship between the members in each drawing are merely schematically represented, and do not necessarily coincide with a relationship in a semiconductor device or the like actually manufactured. For convenience of description, it is also assumed that the size relationship between the members is exaggerated.

In addition, the semiconductor device exemplified in the following description is applied to, for example, a power conversion device such as an inverter of an industrial or in-vehicle motor. Thus, in the following description, detailed description of the same or similar configuration, function, operation, and the like as those of the known semiconductor device will be omitted.

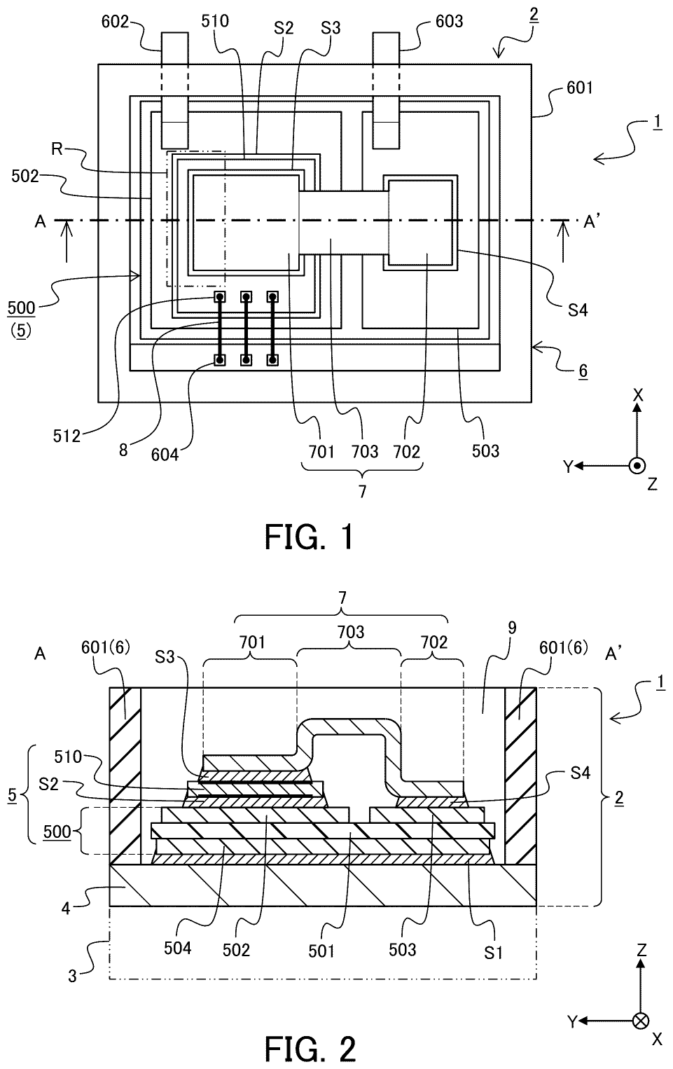

FIG. 1 is a top view illustrating a configuration example of a semiconductor device according to an embodiment. FIG. 2 is a cross-sectional view taken along line A-A′ of the semiconductor device in FIG. 1. In FIG. 1, a sealing material filling a case is omitted. In addition, in FIG. 2, hatching indicating a cross section of the sealing material filling the case is omitted.

As exemplified in FIGS. 1 and 2, a semiconductor device 1 according to the present embodiment is configured by disposing a semiconductor module 2 on an upper surface of a cooler 3. Note that the cooler 3 is an arbitrary configuration with respect to the semiconductor module 2.

The cooler 3 dissipates heat of the semiconductor module 2 to the outside and has a rectangular parallelepiped shape as a whole. Although not particularly illustrated, the cooler 3 is configured by providing a plurality of fins on a lower surface side of a flat plate-shaped base portion and housing these fins in a water jacket. Note that the cooler 3 is not limited to this configuration and can be changed as appropriate.

The semiconductor module 2 includes a base 4, a circuit board 5, a case 6, a lead 7, bonding materials S1 to S4, bonding wires 8, and a sealing material 9.

The base 4 is a substrate on which the circuit board 5 is mounted, and the base 4 on which the circuit board 5 is mounted is attached to a lower surface of the case 6 with the surface on which the circuit board 5 is mounted facing upward. The case 6 includes an insulating member 601 having a rectangular annular shape whose upper surface and lower surface are opened, main terminals 602 and 603 integrated with the insulating member 601, and a plurality of control terminals 604. The circuit board 5 mounted on the base 4 is housed in a hollow portion of the insulating member 601 of the case 6. The base 4 is, for example, a metal plate such as a copper plate and conducts heat generated in the circuit board 5 to the cooler 3. This type of base 4 may be referred to as a heat dissipation plate or a heat dissipation layer. The base 4, which is a heat dissipation plate, may be disposed on the upper surface of the cooler 3, for example, via a thermal conductive material such as a thermal grease or a thermal compound. In addition, the base 4 may be omitted.

The circuit board 5 includes the wiring board 500 and a semiconductor element 510 mounted on an upper surface of the wiring board 500. The wiring board 500 includes an insulating substrate 501, conductor patterns 502 and 503 provided on an upper surface of the insulating substrate 501, and the conductor pattern 504 provided on a lower surface of the insulating substrate 501. The wiring board 500 may be, for example, a direct copper bonding (DCB) substrate or an active metal brazing (AMB) substrate. The wiring board 500 may be referred to as a stacked substrate.

The insulating substrate 501 is not limited to a specific substrate. The insulating substrate 501 may be, for example, a ceramic substrate made of a ceramic material such as aluminum oxide (Al₂O₃), aluminum nitride (AlN), silicon nitride (Si₃N₄), aluminum oxide (Al₂O₃), and zirconium oxide (ZrO₂). The insulating substrate 501 may be, for example, a substrate obtained by molding an insulating resin such as epoxy resin, a substrate obtained by impregnating a base material such as glass fiber with an insulating resin, or a substrate obtained by coating a surface of a flat plate-shaped metal core with an insulating resin.

The conductor patterns 502 and 503 provided on the upper surface of the insulating substrate 501 are conductive members used as wiring members in the circuit board 5, and the conductor pattern 504 provided on the lower surface of the insulating substrate 501 is a conductive member used as a heat dissipation member that conducts heat generated in the circuit board 5 to the base 4. These conductor patterns 502 to 504 are formed of, for example, a metal plate such as copper or aluminum. The conductor pattern 504 provided on the lower surface of the insulating substrate 501 is bonded to the upper surface of the base 4 by the bonding material S1 such as solder. The conductor patterns 502 and 503 provided on the upper surface of the insulating substrate 501 may be each referred to as a conductor layer, a conductor plate, or a wiring pattern. The conductor pattern 504 provided on the lower surface of the insulating substrate 501 may be referred to as a heat dissipation layer, a heat dissipation plate, or a heat dissipation pattern.

As described above, the conductor patterns 502 and 503 provided on the upper surface of the insulating substrate 501 are conductive members used as wiring members in the circuit board 5. In the semiconductor module 2 exemplified in FIGS. 1 to 4, the semiconductor element 510 is mounted on the upper surface of the first conductor pattern 502. In the semiconductor element 510, a first main electrode (not illustrated) provided on the lower surface is bonded to the first conductor pattern 502 by the bonding material S2.

A second main electrode (not illustrated) and control electrodes 512 are provided on the upper surface of the semiconductor element 510. These electrodes are electrically insulated by an insulating layer (not illustrated) formed on the upper surface of the semiconductor element 510. The insulating layer may be a surface protective film such as a passivation film formed on the upper surface of the semiconductor element 510. The second main electrode is electrically connected, via the lead 7, to the second conductor pattern 503 provided on the upper surface of the insulating substrate 501. The lead 7 includes a first bonding portion 701, a second bonding portion 702, and a wiring portion 703 connecting the first bonding portion 701 and the second bonding portion 702. The first bonding portion 701 is electrically connected to the second main electrode of the semiconductor element 510 by the bonding material S3. The second bonding portion 702 is bonded to the second conductor pattern 503 of the wiring board 500 by the bonding material S4. The control electrodes 512 on the upper surface of the semiconductor element 510 are electrically connected, via the bonding wires 8, to the control terminals 604 provided on the case 6.

In the semiconductor module 2 exemplified in FIGS. 1 and 2, the first conductor pattern 502 is electrically connected to the first main terminal 602 provided in the case 6, and the second conductor pattern 503 is electrically connected to the second main terminal 603 provided in the case 6. It is sufficient if a method of electrically connecting the first conductor pattern 502 and the first main terminal 602 and electrically connecting the second conductor pattern 503 and the second main terminal 603 is any of known connection methods, and the method is not limited to a specific method. In addition, the shapes and positions of the main terminals 602 and 603, the number, positions, and the like of the control terminals 604 in the case 6 are not limited to those illustrated, and can be changed as appropriate. Further, the case 6 of the semiconductor module 2 of the present embodiment may be provided with a third main terminal, which is not illustrated, and the like.

In the present embodiment, the semiconductor element 510 includes, for example, a reverse conducting (RC)-IGBT element in which the functions of an insulated gate bipolar transistor (IGBT) element and a free wheeling diode (FWD) element are integrated.

Note that the semiconductor element mounted on the upper surface of the wiring board 500 is not limited to a specific one. A semiconductor element as a switching element such as the IGBT or the power metal oxide semiconductor field effect transistor (MOSFET) and a semiconductor element as a diode element such as the FWD may be mounted on the upper surface of the wiring board 500. In addition, a reverse blocking (RB)-IGBT or the like having a sufficient withstand voltage against a reverse bias may be used as the semiconductor element. The semiconductor element is formed of a semiconductor substrate such as silicon (Si) or silicon carbide (SiC) in a rectangular shape in plan view. Note that the shape, disposition number, disposition location, and the like of the semiconductor element can appropriately be changed. The layout of the conductor pattern as the wiring member provided on the upper surface side of the wiring board 500 is changed according to the type and shape of the semiconductor element to be mounted, the number of the semiconductor elements to be disposed, the location of the semiconductor elements to be disposed, and the like.

When the switching element of the semiconductor element 510 is the IGBT element, the second main electrode on the upper surface side may be referred to as an emitter electrode, and the first main electrode on the lower surface side may be referred to as a collector electrode. When the switching element of the semiconductor element 510 is the MOSFET element, the second main electrode on the upper surface side may be referred to as a source electrode, and the first main electrode on the lower surface side may be referred to as a drain electrode. In addition, the control electrodes 512 provided on the upper surface of the semiconductor element 510 may include a gate electrode and an auxiliary electrode. For example, the auxiliary electrode may be an auxiliary emitter electrode or an auxiliary source electrode electrically connected to the second main electrode and serving as a reference potential with respect to a gate potential. In addition, the auxiliary electrode may be a temperature sensing electrode that is electrically connected to a temperature sensing portion and measures the temperature of the semiconductor element 510. Such electrodes (the second main electrode and the control electrodes 512 including a gate electrode and an auxiliary electrode) formed on the upper surface of the semiconductor element 510 may be generally referred to as upper surface electrodes.

The lead 7 described above is formed by bending a metal plate such as a copper plate, and may be referred to as a lead frame or a metal wiring board. On the upper surface of the semiconductor element 510, an insulating layer is formed so as to surround the second main electrode electrically connected to the first bonding portion 701 of the lead 7. The spread of the bonding material S3 with which the second main electrode and the first bonding portion 701 of the lead 7 are bonded is restricted in a plane (XY plane) at the time of melting by the insulating layer surrounding the second main electrode.

An end portion of the wiring portion 703 of the lead 7 on the first bonding portion 701 side is connected to one side surface of the first bonding portion 701 and is bent from the side surface in a direction opposite to a lower surface (in other words, a surface of the first bonding portion 701 facing the second main electrode of the semiconductor element 510) of the first bonding portion 701. Similarly, an end portion of the wiring portion 703 of the lead 7 on the second bonding portion 702 side is connected to one side surface of the second bonding portion 702 and is bent from the side surface in a direction opposite to a lower surface (in other words, a surface of the second bonding portion 702 facing the conductor pattern 503) of the second bonding portion 702.

The semiconductor element 510, the lead 7, the bonding wires 8, and the like housed in the case 6 are sealed by the sealing material 9. The sealing material 9 may be a single insulating material or a combination of a plurality of types of insulating materials having different compositions (characteristics).

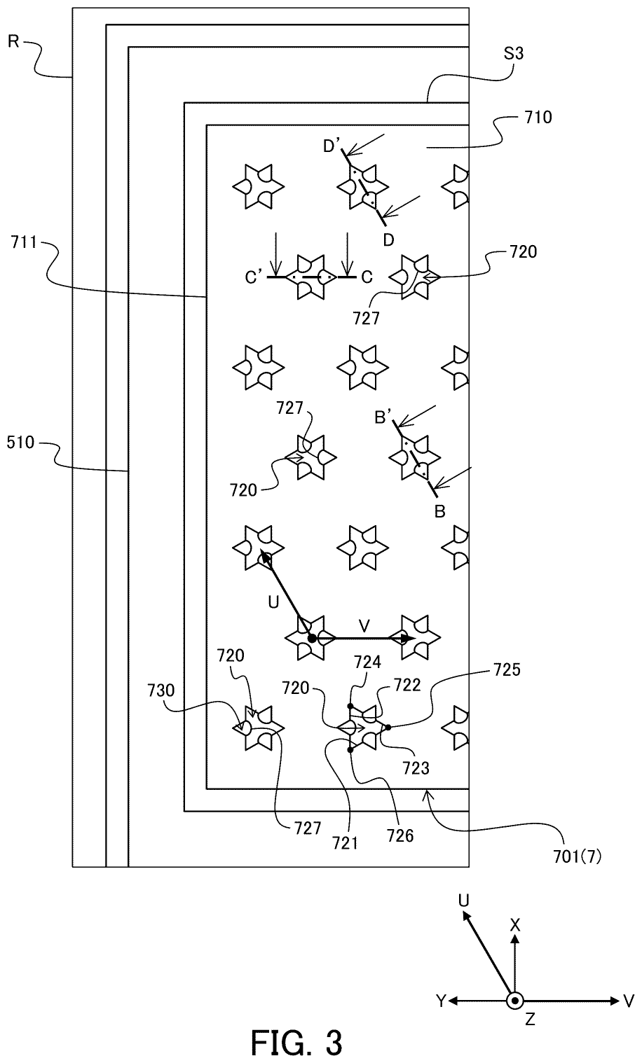

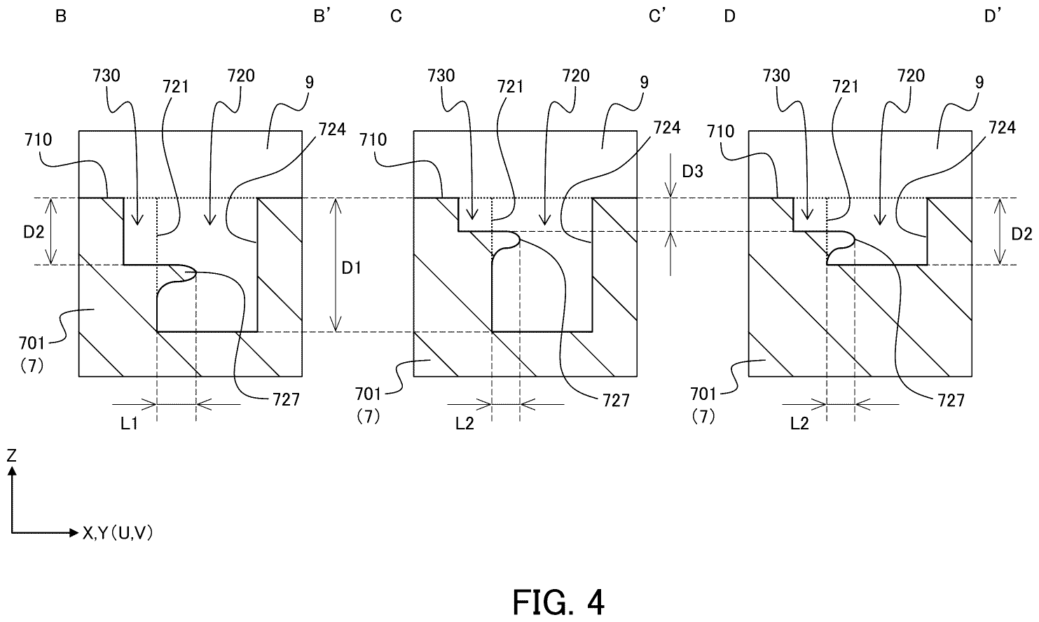

Although not illustrated in FIG. 1, in the semiconductor device 1 of the present embodiment, for example, a plurality of recesses for preventing delamination at the interface between the first bonding portion 701 and the sealing material 9 is provided on the upper surface (the surface opposite to the surface facing the semiconductor element 510) of the first bonding portion 701 of the lead 7. A first example of the plurality of recesses provided on the upper surface of the first bonding portion 701 will be described below with reference to FIGS. 3 and 4.

FIG. 3 is an enlarged partial top view of a region R in FIG. 1. FIG. 4 is a cross-sectional view taken along line B-B′, a cross-sectional view taken along line C-C′, and a cross-sectional view taken along line D-D′ of the portion illustrated in FIG. 3. In FIG. 3, the sealing material 9 filling the case 6 is omitted. In addition, each cross-sectional view of FIG. 4 illustrates only a part of the upper surface side of the first bonding portion 701 and a part of the sealing material 9, and hatching illustrating a cross section of the sealing material 9 loaded in the case 6 is omitted.

On an upper surface 710 of the first bonding portion 701 exemplified in FIG. 3, a plurality of recesses 720 having a bottom surface having an equilateral triangle shape is disposed in a hexagonal lattice shape (also referred to as a triangular lattice shape) in which basic translation vectors are set in a U direction and a V direction. In FIG. 3, a direction rotated −30 degrees with respect to the X direction (a direction rotated 30 degrees counterclockwise) is defined as the U direction, and a direction opposite to the Y direction is defined as the V direction, but the U direction and the V direction are not limited to a specific direction. In addition, in FIG. 3, the bottom surface of each recess 720 is indicated by an equilateral triangle, but the planar shape of the bottom surface is not limited thereto, and may be a substantially equilateral triangle with rounded corners.

The plurality of recesses 720 is disposed such that one wall surface (wall surface 722 in FIG. 3) is in an orientation substantially parallel to the side to which the wiring portion 703 is connected (and a side 711 on the opposite side) on the upper surface 710 of the first bonding portion 701. In addition, in the plurality of recesses 720, there are a first orientation in which a corner 724 facing a wall surface 721 orthogonal to the U direction is located on a +U direction side as viewed from the wall surface 721 and a second orientation in which the corner 724 is located on a −U direction side as viewed from the wall surface 721.

In the recess 720, barbed portions 727 projecting in the directions of opposing corners 724, 725, and 726 are formed on three respective wall surfaces 721, 722, and 723 (see FIG. 4). The barbed portion 727 is provided by forming an additional recess (hereinafter referred to as an “additional recess”) 730 shallower than the depth of the recess 720 in each of portions constituting the wall surfaces 721, 722, and 723 of the recess 720 in the lead 7 (first bonding portion 701). That is, the recess 720 is extended outward in plan view by the additional recess 730 formed on each of the wall surfaces 721, 722, and 723, and the barbed portion 727 protrudes toward the corner facing each wall surface at the position where the additional recess 730 is formed. As will be described below, the additional recess 730 exemplified in FIG. 3 can be formed using a die used for forming the recess 720.

Further, in the first example of the plurality of recesses 720, for example, as illustrated in FIG. 4, the combination of the depth of the recess 720 and the depth of the additional recess 730 (in other words, the position of the barbed portion 727 in the depth direction) is roughly divided into three. In the first combination, as illustrated in a cross-sectional view taken along line B-B′ in FIG. 4, the recess 720 has a depth D1, and the additional recess 730 has a depth D2 (<D1). In the second combination, as illustrated in a cross-sectional view taken along line C-C′ in FIG. 4, the recess 720 has a depth D1, and the additional recess 730 has a depth D3 (<D2). In the third combination, as illustrated in a cross-sectional view taken along line D-D′ in FIG. 4, the recess 720 has a depth D2, and the additional recess 730 has a depth D3. The depths D1, D2, and D3 are not limited to a specific depth. The depths D1, D2, and D3 may be, for example, 100 μm, 50 μm, and 25 μm, respectively.

The protrusion amount of the barbed portion 727 formed on the wall surfaces 721, 722, and 723 of the recess 720 from each wall surface depends on the depth of the additional recess 730. For example, a protrusion amount L1 of the barbed portion 727 formed by the additional recess 730 having the depth D2 is larger than a protrusion amount L2 of the barbed portion 727 formed by the additional recess 730 having the depth D3 (<D2).

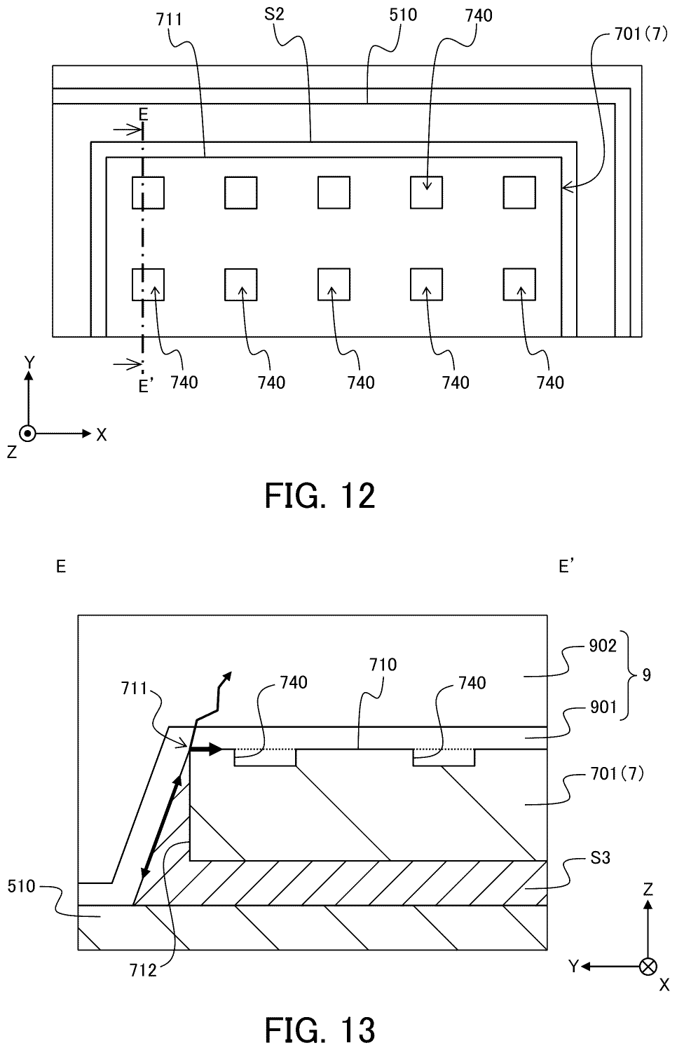

When the plurality of recesses 720 described above is provided on the upper surface 710 of the first bonding portion 701 of the lead 7, the sealing material 9 on the first bonding portion 701 fills the recess 720, so that the contact area between the upper surface 710 of the first bonding portion 701 and the sealing material 9 increases. In addition, since the barbed portion 727 protrudes from each wall surface of the recess 720, a portion of the sealing material 9 in the recess 720 is less likely to come out of the recess 720. Therefore, as compared with the conventional example described below with reference to FIGS. 12 and 13, delamination is less likely to occur at the interface between the first bonding portion 701 of the lead 7 and the sealing material 9. The recess 720 formed in the lead 7 for the purpose of preventing such delamination of the sealing material 9 may be referred to as a roughening hole. In addition, the treatment of forming the recess 720 in the lead 7 may be referred to as a roughening treatment.

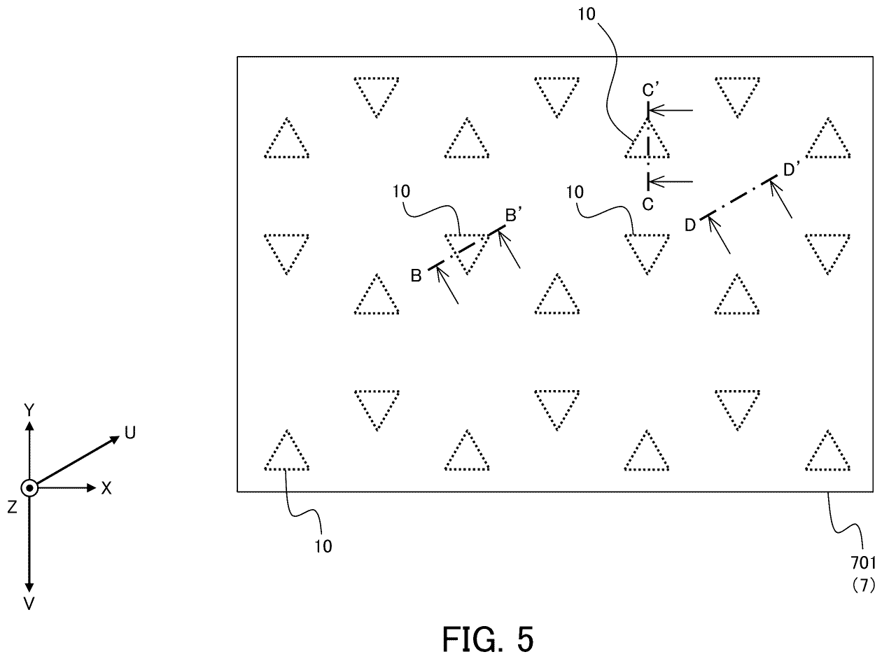

Next, an example of a method of forming the recess 720 having the barbed portions 727 described above with reference to FIGS. 3 and 4 on the upper surface 710 of the first bonding portion 701 of the lead 7 will be described with reference to FIGS. 5 to 11.

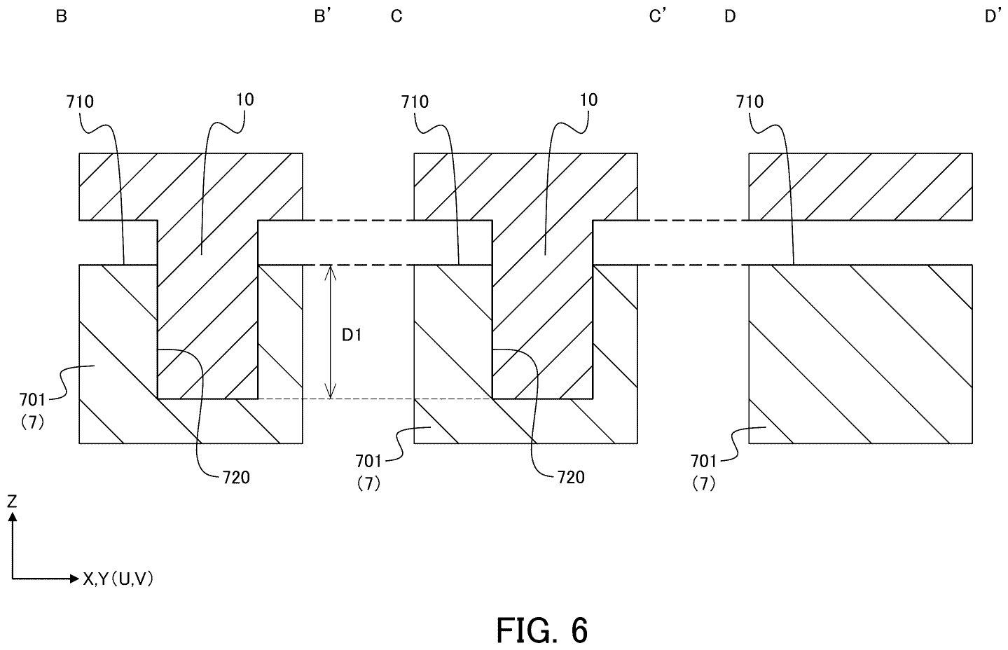

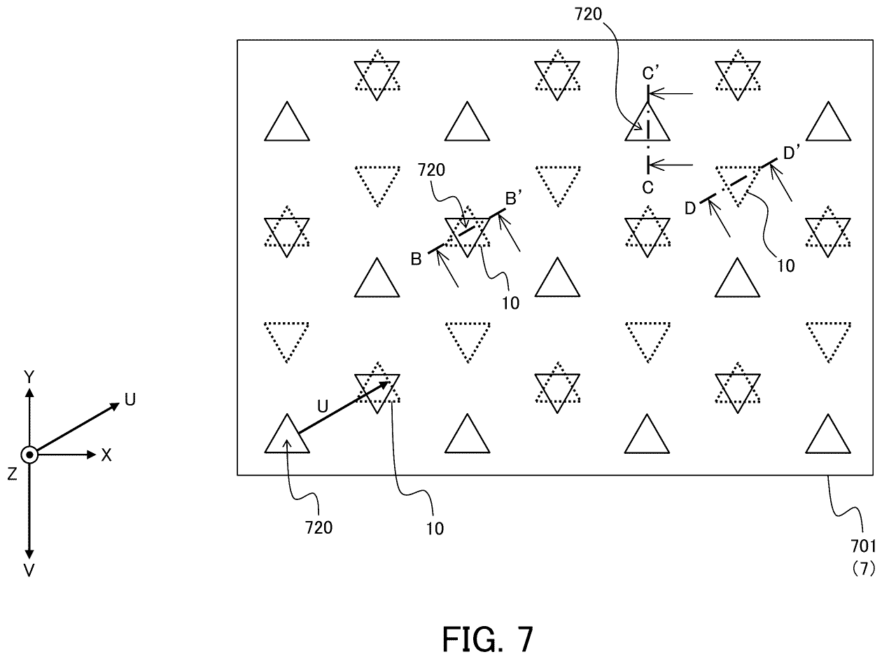

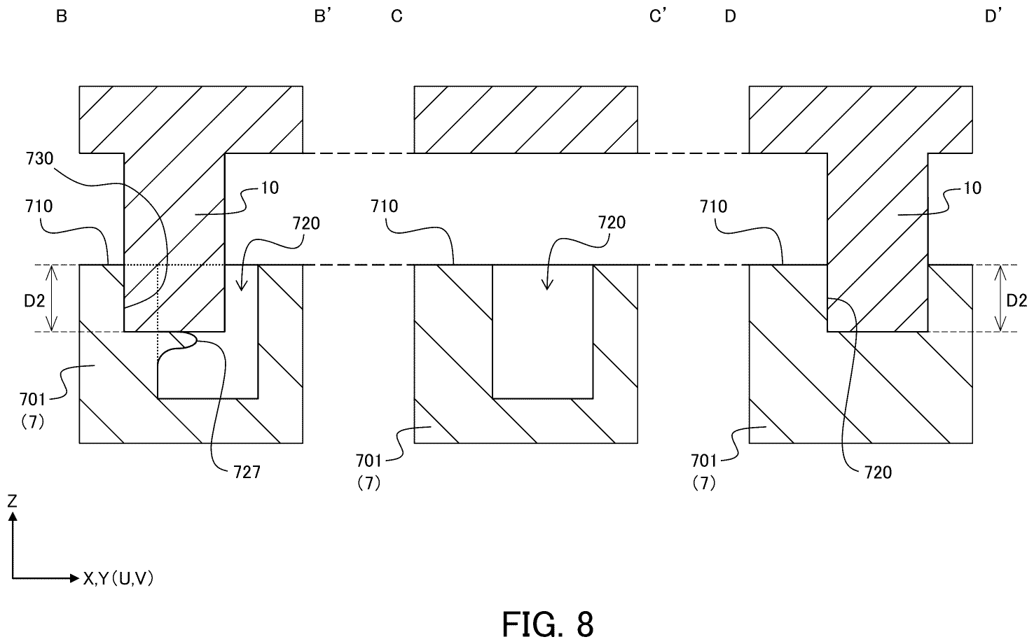

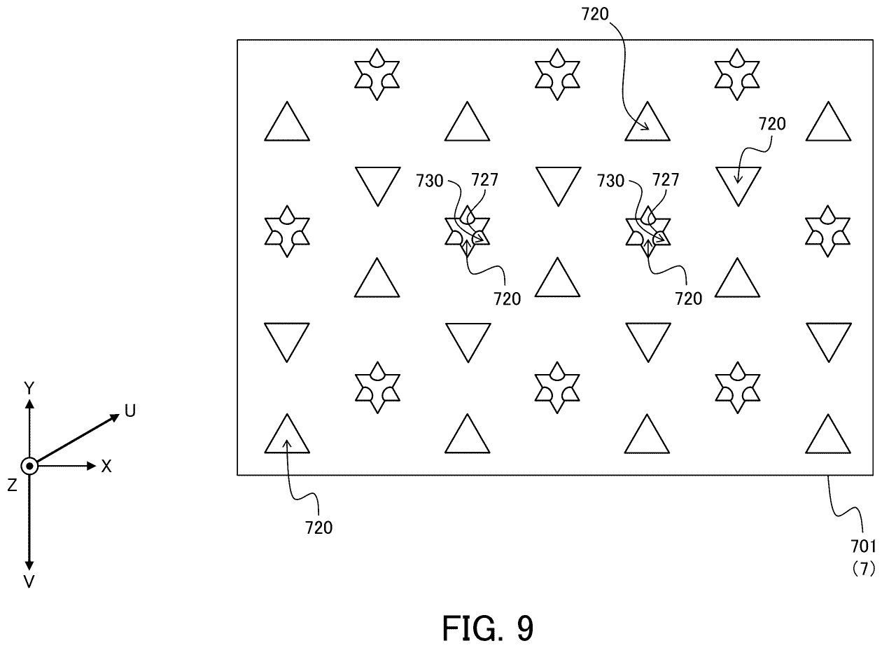

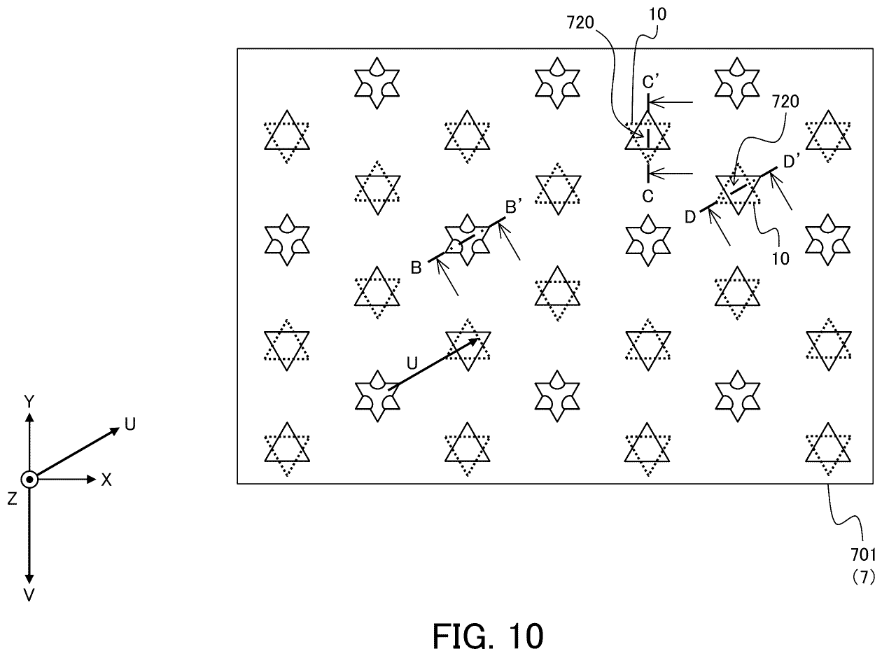

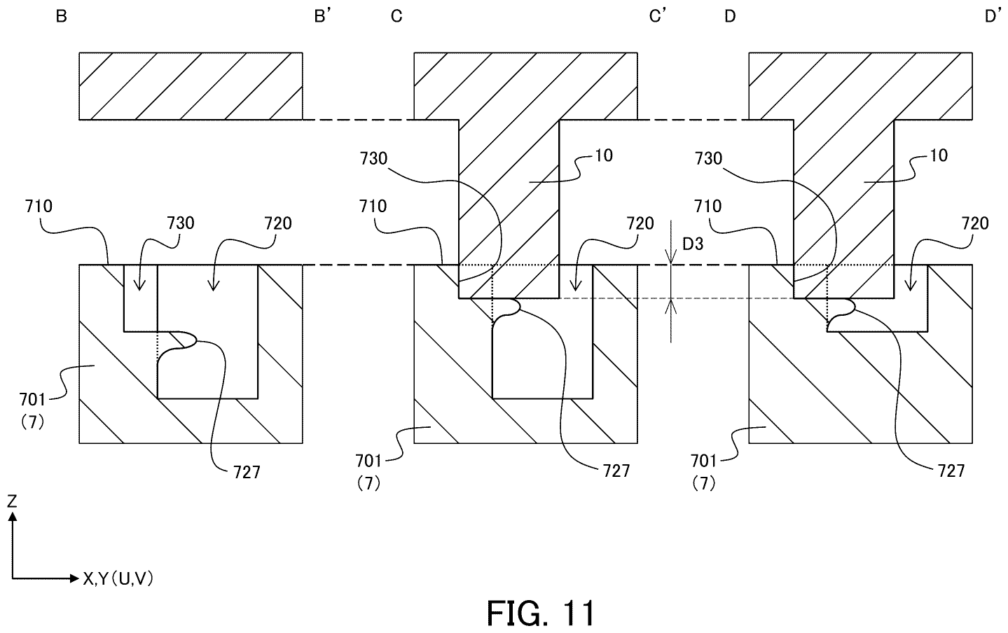

FIG. 5 is a top view describing a first step in an example of a method of forming a recess. FIG. 6 is a cross-sectional view taken along line B-B′, a cross-sectional view taken along line C-C′, and a cross-sectional view taken along line D-D′ in FIG. 5. FIG. 7 is a top view describing a second step in an example of a method of forming a recess. FIG. 8 is a cross-sectional view taken along line B-B′, a cross-sectional view taken along line C-C′, and a cross-sectional view taken along line D-D′ in FIG. 7. FIG. 9 is a top view describing recesses formed in the first step and the second step. FIG. 10 is a top view describing a third step in an example of a method of forming a recess. FIG. 11 is a cross-sectional view taken along line B-B′, a cross-sectional view taken along line C-C′, and a cross-sectional view taken along line D-D′ in FIG. 10. The top views of FIGS. 5, 7, and 10 illustrate a state in which a die (punch 10 to be described below) for forming the recess 720 or the additional recess 730 is pressed against the first bonding portion 701 of the lead 7 in a corresponding step, and triangles indicated by the dotted lines illustrate the shape of the punch 10.

In an example of the method, first, the first step of forming some of the plurality of recesses 720 having a triangular prism shape on the upper surface 710 of the first bonding portion 701 of the lead 7 is performed. In the first step, as exemplified in FIGS. 5 and 6, among the recesses 720 disposed in a hexagonal lattice shape, only the recesses 720 are formed such that two adjacent equilateral triangles adjacent to each other in a positional relationship represented by the basic translation vector have a distance between sides parallel to each other that is shorter than a distance between corners facing the sides. In other words, in the first step, the six recesses 720 annularly disposed in the positional relationship represented by the basic translation vector are formed in an orientation protruding toward the center side of the regular hexagon connecting the formation positions of the six recesses 720, and the recess 720 is not formed at the center of the regular hexagon.

Note that, in the first step, as exemplified in FIG. 6, the recess 720 having the depth D1 is formed by the punch 10. The depth D1 is, for example, 100 μm.

After the first step, the second step of forming the remaining recesses 720 of the plurality of recesses 720 having a triangular prism shape and the additional recesses 730 for some of the recesses 720 formed in the first step is performed. As exemplified in FIG. 7, the second step is performed by shifting the relative position between the punch 10 used in the first step and the first bonding portion 701 of the lead 7 by a direction and a distance corresponding to the basic translation vector in the U direction in plan view. At this time, by disposing the recesses 720 formed in the first step as described above with reference to FIG. 5, some of the punches 10 move to positions where the recess 720 was not formed in the first step. In addition, by setting the orientation of the bottom surface (equilateral triangle) of the recess 720 formed in the first step to the orientation described above with reference to FIG. 5, the orientation of the bottom surface (equilateral triangle) of the punch 10 moved to the position where the recess 720 is formed in the first step is opposite to the orientation of the bottom surface (equilateral triangle) of the recess 720. That is, the corners of the bottom surface of the punch 10 moved to the position where the recess 720 was formed in the first step are located outside the recess 720. Therefore, by the punch 10 used in the first step, as exemplified in FIG. 9, it is possible to form the recesses 720 having a triangular prism shape not formed in the first step and the additional recesses 730 for some of the recesses 720 having a triangular prism shape formed in the first step. At this time, the bottom surface of the additional recess 730 has a triangular shape.

Note that, in the second step, as exemplified in FIG. 8, the recess 720 and the additional recess 730 having the depth D2 shallower than the depth D1 are formed by the punch 10. The depth D2 is, for example, 50 μm.

When the second step is ended, as exemplified in FIG. 9, the recess 720 having a triangular prism shape in which the additional recess 730 is not formed and the recess 720 in which the additional recess 730 is formed and which has the barbed portion 727 are disposed in a hexagonal lattice shape. At this time, as illustrated in the cross-sectional views taken along line B-B′ in FIGS. 4 and 8, the recess 720 having the barbed portion 727 has the depth D1, and has the barbed portion 727 having the protrusion amount L1 at a position corresponding to the depth D2 of the additional recess 730. In addition, among the recesses 720 having no barbed portion 727, the recess 720 formed in the first step has the depth D1 as illustrated in the cross-sectional views taken along line C-C′ in FIGS. 4 and 8. In addition, the recess 720 formed in the second step has the depth D2 (<D1) as in the cross-sectional views taken along line D-D′ in FIGS. 4 and 8. Further, the bottom surface of the additional recess 730 has a triangular shape.

After the second step, the third step of forming the additional recesses 730 for the plurality of recesses 720 having a triangular prism shape in which the additional recesses 730 were not formed in the second step is performed. As exemplified in FIG. 10, the third step is performed by further shifting the relative position between the punch 10 used in the first step and the second step and the first bonding portion 701 of the lead 7 by a direction and a distance corresponding to the basic translation vector in the U direction in plan view. At this time, by disposing the recesses 720 formed in the first step as described above with reference to FIG. 5, the punch 10 moves to the position of the recess 720 where the additional recess 730 was not formed in the second step. In addition, by setting the orientation of the bottom surface (equilateral triangle) of the recess 720 formed in the first step to the orientation described above with reference to FIG. 5, the orientation of the bottom surface (equilateral triangle) of the punch 10 moved to the position of the recess 720 where the additional recess 730 is not formed in the third step is opposite to the orientation of the bottom surface (equilateral triangle) of the recess 720. That is, the corners of the bottom surface of the punch 10 moved to the position where the recess 720 was formed in the first step or the second step are located outside the recess 720. Therefore, by the punch 10 used in the first step and the second step, the additional recess 730 can be formed for all of the recesses 720 having a triangular prism shape in which the additional recess 730 is not formed.

Note that, in the third step, as exemplified in FIG. 11, the additional recess 730 having the depth D3 shallower than the depth D2 is formed by the punch 10. The depth D3 is, for example, 25 μm.

The method described above with reference to FIGS. 5 to 11 is merely an example of a method of forming the recess 720 having the three wall surfaces 721, 722, and 723 and having the barbed portion 727 on each of the three wall surfaces 721, 722, and 723 on the upper surface 710 of the first bonding portion 701 of the lead 7.

FIG. 12 is a top view describing a conventional example of a recess for preventing delamination at an interface between a first bonding portion of a lead and a sealing material. FIG. 13 is a cross-sectional view taken along line E-E′ of the portion illustrated in FIG. 12. FIG. 12 illustrates a region corresponding to the region R in FIG. 1. In FIG. 13, only a portion related to delamination at the interface between the first bonding portion of the lead and the sealing material is illustrated, and hatching indicating cross sections of a coating agent and a sealing resin as the sealing material 9 is omitted.

On the upper surface 710 of the first bonding portion 701 of the lead 7 exemplified in FIGS. 12 and 13, recesses 740 having a rectangular bottom surface are provided in a square lattice shape as recesses for preventing delamination at the interface with the sealing material 9. The wall surface of the recess 740 includes a wall surface substantially parallel to the side of the upper surface 710 of the first bonding portion 701 to which the wiring portion 703 is connected (and the side 711 on the opposite side), and a wall surface substantially perpendicular to the side 711. In addition, the barbed portion 727 described above with reference to FIGS. 3 to 11 is not formed on the wall surface of the recess 740.

In the conventional example of the semiconductor device using the lead 7 exemplified in FIGS. 12 and 13, for example, as exemplified in FIG. 13, a coating agent 901 for coating the semiconductor element 510 and the lead 7 (first bonding portion 701) and a sealing resin 902 for sealing the semiconductor element 510, the lead 7, and the like coated with the coating agent 901 are used as the sealing material 9. The coating agent 901 may be, for example, an insulating material such as polyamide (PA). The sealing resin 902 may be an epoxy resin, silicone gel, or the like, for example.

When the second main electrode (not illustrated) on the upper surface of the semiconductor element 510 and the first bonding portion 701 of the lead 7 are bonded by the bonding material S3 such as solder, as exemplified in FIG. 13, a part (excess) of the bonding material S3 crawls up the side surface (side surface 712 in FIG. 13 or the like) of the first bonding portion 701 to generate a fillet. Therefore, there is a section of the coating agent 901 in contact with the bonding material S3 between the section in contact with the semiconductor element 510 and the section in contact with the upper surface 710 of the first bonding portion 701 of the lead 7. Then, at the interface between the coating agent 901 and the bonding material S3, due to a large difference in thermal expansion coefficient between the coating agent 901 and the bonding material S3, a change in stress due to the thermal history of the semiconductor device is large, and delamination may occur. The delamination occurring at the interface between the coating agent 901 and the bonding material S3 propagates to the interface between the coating agent 901 and the upper surface 710 of the first bonding portion 701 of the lead 7. At the interface between the coating agent 901 and the upper surface 710 of the first bonding portion 701 of the lead 7, stress due to a difference in thermal expansion coefficient or the like increases in a direction orthogonal to the side of the upper surface 710 of the first bonding portion 701, and delamination propagates in this direction (in the example of FIG. 13, the delamination propagates in the −Y direction from the position of the side 711). For this reason, as exemplified in FIG. 12, when all the wall surfaces of the recess 740 provided on the upper surface 710 of the first bonding portion 701 are wall surfaces orthogonal to any of the sides of the upper surface 710, delamination is likely to occur at the interface between the wall surface of the recess 740 and the coating agent 901, and the propagation of delamination cannot be prevented in some cases. Then, when delamination at the interface between the coating agent 901 and the upper surface 710 of the first bonding portion 701 of the lead 7 propagates, cracking occurs in the sealing material 9 (coating agent 901 and sealing resin 902), and the semiconductor device may fail.

On the other hand, since the recess 720 of the present embodiment described above with reference to FIGS. 3 to 11 has a triangular prism shape, there is always a wall surface that is not orthogonal to the sides of the upper surface 710 of the first bonding portion 701 of the lead 7. Therefore, as compared with the recess 740 having only the wall surfaces orthogonal to any of the sides of the upper surface 710 as exemplified in FIG. 12, delamination hardly occurs at the interface between the wall surface of the recess 720 and the sealing material 9, and the effect of preventing the propagation of delamination is high. Further, since the recess 720 of the present embodiment has the barbed portion 727 protruding from the wall surface toward the opposing corner, a portion of the sealing material 9 (coating agent 901 or the like) that has entered the recess 720 is less likely to come out of the recess 720. Therefore, in the semiconductor device 1 according to the present embodiment, the effect of preventing the propagation of delamination at the interface between the upper surface 710 of the first bonding portion 701 of the lead 7 and the sealing material 9 is high, and the occurrence of failure due to cracking or the like of the sealing material 9 can be prevented.

Further, as described above with reference to FIG. 3, by disposing the recesses 720 in which the orientation of the bottom surface (equilateral triangle) is the first orientation and the recesses 720 in which the orientation of the bottom surface (equilateral triangle) is the second orientation in a hexagonal lattice shape, a change at the interface between the sealing material 9 and the wall surface of the recess 720 in the direction orthogonal to the side of the upper surface 710 of the first bonding portion 701 of the lead 7 can be made more complicated, and the effect of preventing the propagation of delamination at the interface is further enhanced.

Note that the method of forming the barbed portion 727 on the wall surfaces 721, 722, and 723 of the recess 720 is not limited to the method described above with reference to FIGS. 5 to 11, and may be another method. For example, the punch (pusher) used for forming the recess 720 having a triangular prism shape in the first step, the punch used for forming the recess 720 and the additional recess 730 in the second step, and the punch used for forming the additional recess 730 in the third step may be different punches. In addition, for example, for the recess 720 having the barbed portion 727, for example, the recess 720 having a first depth may be formed on the upper surface 710 of the first bonding portion 701 of the lead 7 using a first punch (pusher), and then the additional recess 730 having a second depth shallower than the first depth may be formed for all of the recesses 720 using a second punch (pusher). Such a forming method is effective, for example, when the number of recesses 720 having a triangular prism shape formed on the upper surface 710 of the first bonding portion 701 is small. When the step of forming the recess 720 and the step of forming the additional recess 730 are performed one by one, the orientation of the bottom surface (equilateral triangle) of the recess 720 may be a single orientation, or may be the first orientation and the second orientation as described above.

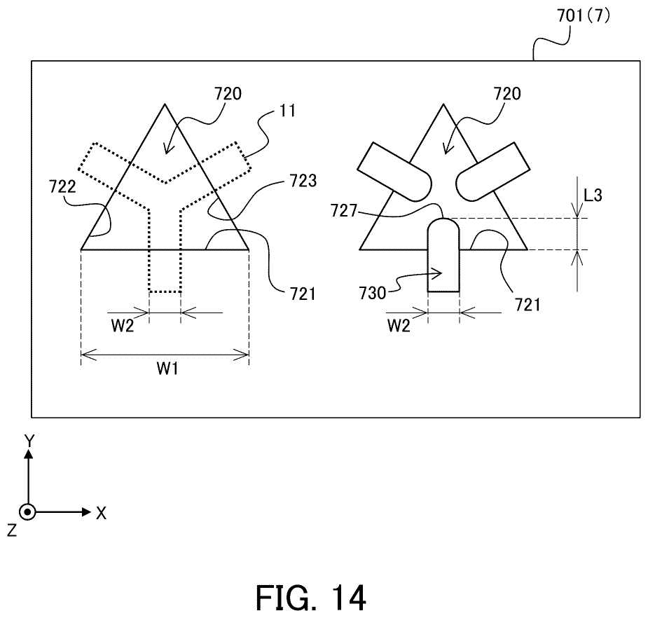

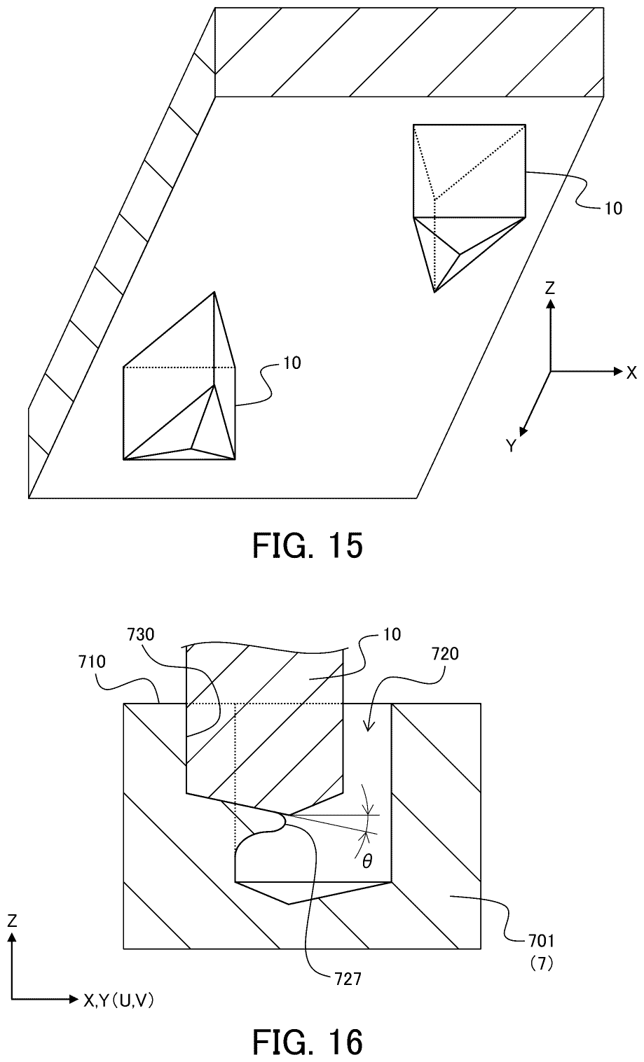

FIG. 14 is a top view describing a second example of a method of forming a barbed portion on a wall surface of a recess. FIG. 15 is a perspective view describing a third example of a method of forming a barbed portion on a wall surface of a recess. FIG. 16 is a cross-sectional view illustrating an example of a recess and an additional recess formed using a punch exemplified in FIG. 15.

The method of forming the barbed portion 727 protruding toward the opposite corner on each of the wall surfaces 721, 722, and 723 of the recess 720 having a triangular prism shape is not limited to the above-described press working using the punch 10 having a triangular prism shape. For example, the additional recess 730 for forming the barbed portion 727 may be formed by press working using a punch having a Y-shaped bottom surface 11 in plan view as indicated by the dotted lines in FIG. 14. In the case of using this type of punch, a ratio W2/W1 of a side length W1 of the recess 720 having a triangular prism shape formed by the punch 10 in plan view to a dimension W2 of the additional recess 730 formed in the direction of the side of the recess 720 can be set to an arbitrary value. Therefore, for example, by adjusting the ratio W2/W1 and the depth of the additional recess 730, the barbed portion 727 having a desired protrusion amount L3 can be formed. The shape of the barbed portion 727 in plan view can also be adjusted by adjusting the ratio W2/W1 and the depth of the additional recess 730. For this reason, for example, the area of the barbed portion 727 in a plan view is increased (that is, the inflow path of the sealing material from the opening end side of the recess 720 to the bottom surface becomes narrow), and it is possible to prevent the sealing material 9 from being insufficiently loaded between the barbed portion 727 and the bottom surface of the recess 720.

In addition, for the punch 10 used for forming the recess 720 and the additional recess 730, for example, as exemplified in FIG. 15, the bottom surface of the punch 10 may have a triangular pyramidal convex shape. When such a punch 10 is used, as exemplified in FIG. 16, the bottom surface of the recess 720 has a triangular pyramidal concave shape, and thus the contact area between the sealing material 9 and the bottom surface of the recess 720 increases. Similarly, the contact area between the sealing material 9 and the bottom surface of the additional recess 730 increases. Further, by forming the additional recess 730 using the punch 10 having a bottom surface having a triangular pyramidal convex shape, for example, the protruding direction of the barbed portion 727 is inclined to the bottom surface side an angle θ from the direction perpendicular to the wall surfaces 721, 722, and 723, and the effect of preventing the sealing material 9 from coming out of the recess 720 by the barbed portion 727 is further enhanced.

Note that the recess 720 described above is described assuming that the shape of the bottom surface in plan view is an equilateral triangle. However, the shape of the bottom surface of the recess 720 in plan view is not limited to an equilateral triangle, but may be another triangular shape. In addition, the shape of the bottom surface of the recess 720 in plan view is not limited to the triangular shape, but may be a polygonal shape having sides extending in directions not orthogonal to any side of the first bonding portion 701 of the lead 7. In addition, when the recess 720 and the additional recess 730 are formed using the punch 10 having a convex bottom surface described above with reference to FIGS. 15 and 16, the shape of the bottom surface of the punch 10 is not limited to the above-described triangular pyramidal convex shape, but may be another convex shape.

Note that the recesses 720 having the barbed portions 727 on the wall surfaces described in the above embodiment may be disposed in a hexagonal lattice shape on the entire upper surface 710 of the first bonding portion 701 of the lead 7, or may not be disposed in a specific region of the upper surface 710. Further, the recess 720 may be formed not only on the upper surface 710 of the first bonding portion 701 of the lead 7, but also on, for example, the upper surface of the second bonding portion 702.

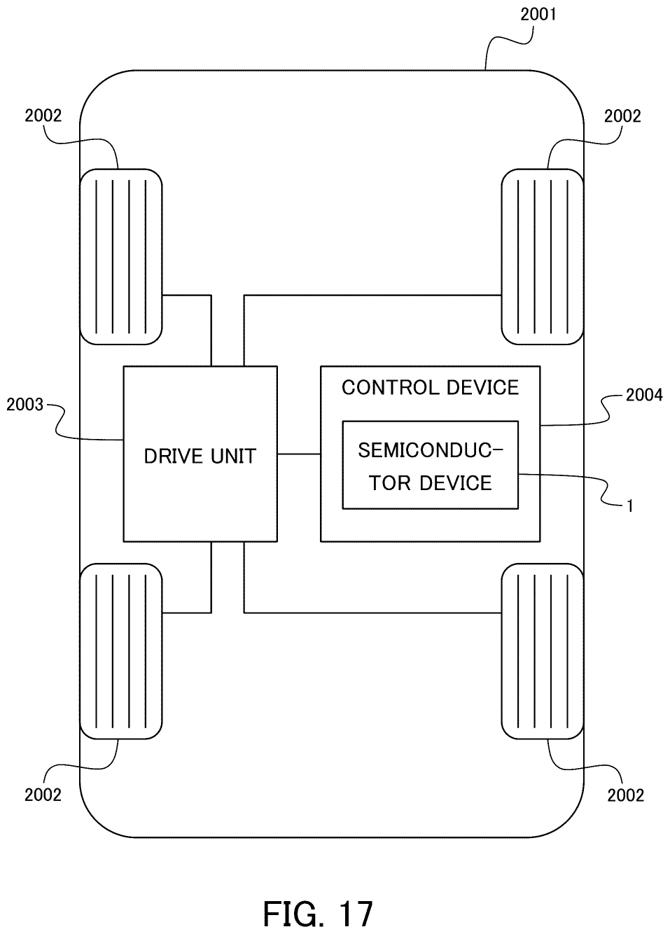

As described above, the semiconductor device 1 including the semiconductor module 2 of the present embodiment can be applied to the power conversion device such as the inverter of the in-vehicle motor. A vehicle to which the semiconductor device 1 according to the present invention is applied will be described with reference to FIG. 17.

FIG. 17 is a schematic plan view illustrating an example of a vehicle to which the semiconductor device according to the present invention is applied. A vehicle 2001 illustrated in FIG. 17 is configured with, for example, a four-wheeled vehicle including four wheels 2002. The vehicle 2001 may be, for example, an electric vehicle that drives wheels with a motor or the like, or a hybrid vehicle using power of an internal combustion engine in addition to the motor.

The vehicle 2001 includes a drive unit 2003 that imparts power to the wheels 2002 and a control device 2004 that controls the drive unit 2003. The drive unit 2003 may be configured with, for example, at least one of an engine, a motor, and a hybrid of the engine and the motor.

The control device 2004 performs control (for example, power control) of the drive unit 2003 described above. The control device 2004 includes the semiconductor device 1 described above. The semiconductor device 1 may be configured to perform the power control on the drive unit 2003.

In the semiconductor module 2 of the semiconductor device 1 used for this type of vehicle 2001, when the first bonding portion 701 of the lead 7 described above is bonded to the electrode (for example, the second main electrode of the semiconductor element 510) on the upper surface of the semiconductor element by the bonding material S3, it is possible to prevent the propagation of delamination at the interface between the sealing material 9 and the upper surface 710 of the first bonding portion 701. Therefore, it is possible to reduce the frequency of inspection and replacement of the semiconductor device 1 used in the vehicle 2001.

Note that the vehicle to which the semiconductor device 1 is applied is not limited to the four-wheeled vehicle exemplified in FIG. 17. The vehicle to which the semiconductor device 1 is applied includes a railway vehicle or the like.

Although the present embodiment and the modifications have been described above, the above-described embodiment and modifications may be wholly or partially combined as another embodiment.

In addition, the present embodiment is not limited to the above-described embodiment and modifications, and various changes, substitutions, and modifications may be made without departing from the spirit of the technical idea. In addition, if the technical idea can be achieved in another manner by the progress of the technology or another derived technology, the technology may be implemented by using the method. Therefore, the claims cover all embodiments that may be included within the scope of the technical idea.

The feature points in the above embodiment will be described below.

A semiconductor module according to the above embodiment includes: a circuit board on which a semiconductor element is mounted; a lead that is bonded to an electrode on an upper surface of the semiconductor element by a bonding material; and a sealing material that seals the semiconductor element and the lead, in which the lead includes a plurality of recesses having a polygonal shape in which a bottom surface in plan view has a side extending in a direction not orthogonal to any of sides of a bonding portion on an upper surface of the bonding portion bonded to the electrode, the upper surface being opposite to a lower surface facing the electrode, and each of the plurality of recesses has a barbed portion protruding from a wall surface.

In the semiconductor module according to the above embodiment, the recess has a bottom surface having a triangular shape in plan view, and has an additional recess that is extended outward of the recess from the wall surface and shallower than a depth to the bottom surface of the recess, and the barbed portion protrudes from the wall surface at a position of a bottom surface of the additional recess.

In the semiconductor module according to the above embodiment, the recesses are disposed in a hexagonal lattice shape in plan view, and include a recess having a bottom surface having a triangular shape in a first orientation in plan view and a recess having a bottom surface having a triangular shape in plan view in a second orientation opposite to the first orientation.

In the semiconductor module according to the above embodiment, the bottom surface of the additional recess in plan view has a triangular shape.

In the semiconductor module according to the above embodiment, the plurality of recesses includes a plurality of types of recesses having different combinations of a depth to the bottom surface and a depth to the bottom surface of the additional recess.

In the semiconductor module according to the above embodiment, the bottom surface of the additional recess in plan view has a rectangular shape.

In the semiconductor module according to the above embodiment, at least one of the bottom surface of the recess and the bottom surface of the additional recess has a concave shape.

A semiconductor device according to the embodiment includes: the semiconductor module described above; and a cooler that is disposed on a surface of the circuit board of the semiconductor module on a side opposite to a surface on which the semiconductor element is mounted.

A vehicle according to the embodiment includes the semiconductor module or the semiconductor device described above.

### INDUSTRIAL APPLICABILITY

As described above, the present invention has the effect of being able to prevent propagation of delamination at an interface between an upper surface of a bonding portion of a lead bonded to an electrode of a semiconductor element and a sealing material, and is particularly useful for a semiconductor module for industrial or electrical equipment, a semiconductor device, and a vehicle.

The present application is based on Japanese Patent Application No. 2022-161588 filed on Oct. 6, 2022. All the contents are included herein.

1. A semiconductor module comprising:
a circuit board including a semiconductor element, the semiconductor element having an electrode on an upper surface thereof;
a lead that is bonded to the electrode of the semiconductor element by a bonding material; and
a sealing material that seals the semiconductor element and the lead, wherein
the lead includes:
a bonding portion bonded to the electrode, the bonding portion having a lower surface facing the electrode, and an upper surface opposite to the lower surface, and
a plurality of recesses formed on the upper surface of the bonding portion;
in a plan view of the semiconductor module,
the bonding portion has a plurality of sides, and
each of the plurality of recesses has a bottom surface of a planar shape, the planar shape having a side extending in a direction that is not orthogonal to any of the sides of the bonding portion; and
each of the plurality of recesses has:
a wall surface, and
a barbed portion protruding from the wall surface.

2. The semiconductor module according to claim 1, wherein
the planar shape is a triangular shape,
each of the plurality of recesses has an additional recess that extends outward of said each recess from the wall surface thereof, and that has a bottom surface shallower than the bottom surface of said each recess, and
the barbed portion protrudes from the wall surface of said each recess at a position of the bottom surface of the additional recess.

3. The semiconductor module according to claim 2, wherein
the plurality of recesses include:
a plurality of first recesses, of each of which the planar shape is a triangular shape in a first orientation, and
a plurality of second recesses, of each of which the planar shape is the triangular shape in a second orientation opposite to the first orientation,
the plurality of first recesses and the plurality of second recesses forming a hexagonal lattice pattern.

4. The semiconductor module according to claim 2, wherein
in the plan view, the bottom surface of each of the additional recesses is of a triangular shape.

5. The semiconductor module according to claim 4, wherein
the plurality of recesses includes a plurality of types of recesses having different combinations of
a depth of the bottom surface of each recess, and
a depth of the bottom surface of the additional recess for said each recess.

6. The semiconductor module according to claim 2, wherein
in the plan view, the bottom surface of each of the additional recesses in of a rectangular shape.

7. The semiconductor module according to claim 2, wherein
at least one of the bottom surface of said each recess and the bottom surface of the additional recess of said each recess has a concave shape.

8. A semiconductor device comprising:
the semiconductor module according to claim 1, wherein the circuit board further includes a wiring board having:
a first surface on which the semiconductor element is mounted, and
a second surface opposite to the first surface; and
a cooler that is disposed on the second surface of the wiring board.

9. A vehicle comprising the semiconductor module according to claim 1.

10. A vehicle comprising the semiconductor device according to claim 8.
